(19) United States
(12) Patent Application Publication
(10) Pub. No.: US 2016/0035593 A1
(43) Pub. Date: Feb. 4, 2016

(54) DEVICES AND METHODS RELATED TO SUPPORT FOR PACKAGING SUBSTRATE PANEL HAVING CAVITIES

(71) Applicant: SKYWORKS SOLUTIONS, INC., Woburn, MA (US)

(72) Inventors: Matthew Sean READ, Rancho Santa Margarita, CA (US); Howard E. CHEN, Anaheim, CA (US); Sandra Louise PETTY-WEEKS, Newport Beach, CA (US)

(21) Appl. No.: 14/809,239

(22) Filed: Jul. 26, 2015

Related U.S. Application Data
(60) Provisional application No. 62/031,819, filed on Jul. 31, 2014.
(60) Provisional application No. 62/031,820, filed on Jul. 31, 2014.

(51) Int. Cl. H01L 21/56; B29C 43/36; B29C 43/18

(52) U.S. Cl. CPC H01L 21/565; B29C 43/18; B29C 43/36; B29L 2031/3406

(57) ABSTRACT

Devices and methods related to support for packaging substrate panel having cavities. In some embodiments, a device for fabricating radio-frequency (RF) modules can include a support plate having a receiving side configured to receive a packaging substrate panel having a plurality of pockets. The receiving side can include a plurality of support features. Each support feature can be dimensioned to fit at least partially into the corresponding pocket and provide support for a portion of the packaging substrate panel associated with the pocket. Among others, such a device can allow formation of an overmold on the side of packaging substrate panel opposite from the pockets, without mechanical deformation of the packaging substrate panel.

### CROSS-REFERENCE TO RELATED APPLICATION(S)

This application claims priority to U.S. Provisional Application No. 62/031,819 filed Jul. 31, 2014, entitled DEVICES AND METHODS RELATED TO SUPPORT FOR PACKAGING SUBSTRATE PANEL HAVING CAVITIES, and U.S. Provisional Application No. 62/031,820 filed Jul. 31, 2014, entitled DEVICES AND METHODS RELATED TO DUAL-SIDED RADIO-FREQUENCY PACKAGE HAVING SUBSTRATE CAVITY, the disclosure of each of which is hereby expressly incorporated by reference herein in its entirety.

### BACKGROUND

1. Field

The present disclosure relates to fabrication of packaged electronic modules.

2. Description of the Related Art

Packaged electronic modules, such as radio-frequency (RF) modules, are commonly processed while in a panel format. Such a panel format allows an array of many individual units to undergo various process steps in an efficient manner. Once processing of such a panel is complete, the panel can be singulated to yield separate individual units.

### SUMMARY

In some implementations, the present disclosure relates to a device for fabricating radio-frequency (RF) modules. The device includes a support plate having a receiving side configured to receive a packaging substrate panel having a plurality of pockets. The receiving side include a plurality of support features, with each support feature being dimensioned to fit at least partially into the corresponding pocket and provide support for a portion of the packaging substrate panel associated with the pocket.

In some embodiments, the support feature can include a pedestal implemented on the receiving side. The packaging substrate can include an upper side and a lower side when positioned on the receiving side of the support plate, such that the pockets are on the lower side of the packaging substrate and the portion of the packaging substrate panel forms a ceiling for the corresponding pocket. The support plate can be configured to provide underside support for the ceilings of the pockets during a processing operation in which pressure is applied on the upper side of the packaging substrate panel. Such a processing operation can include, for example, a compression molding process implemented to form an overmold layer over the packaging substrate.

In some embodiments, the support plate can be an integral part of a platform for holding the packaging substrate panel during the compression molding process. In some embodiments, the support plate can be configured to fit into a molding cavity of a compression molding apparatus that is configured to receive a substantially flat packaging substrate panel.

In some embodiments, the underside support can be provided at least in part by the pedestals to inhibit or reduce deformation of the ceilings of the pockets. Such a deformation include each ceiling bowing into the corresponding pocket.

In some embodiments, the pedestal can include a substantially flat surface for supporting the corresponding ceiling of the pocket. In some embodiments, the pedestal can include one or more support features dimensioned to accommodate features on the corresponding ceiling of the pocket. In some embodiments, the pedestal can have a rectangular shape with a height dimensioned to provide support for at least a selected area of the ceiling of the pocket. The height can be selected such that an upper surface of the pedestal is in contact with the ceiling of the pocket when providing the support for the selected area. The selected area can be, for example, at least 50% of the area of the ceiling of the pocket, or at least 75% of the area of the ceiling of the pocket.

In a number of teachings, the present disclosure relates to a method for fabricating radio-frequency (RF) modules. The method includes positioning a packaging substrate panel for a processing operation in which pressure is applied on a first side of the packaging substrate panel. The packaging substrate panel includes a plurality of pockets on a second side opposite from the first side. The method further includes supporting, on the second side, a portion of the packaging substrate panel associated with each pocket to reduce deformation of the pocket resulting from the pressure applied on the first side.

In some embodiments, the method can further include performing the processing operation in which the pressure is applied on the first side of the packaging substrate panel. The processing operation can include a compression molding operation to form an overmold layer on the first side of the packaging substrate panel. The method can further include mounting a component within each of the pockets to yield a panel of dual-sided packages. The method can further include singulating the dual-sided packages into a plurality of single units.

In some embodiments, the supporting of the portion of the packaging substrate panel can include positioning the packaging substrate panel on a support plate having a plurality of support features. Each support feature can be dimensioned to fit at least partially into the corresponding pocket and provide support for the corresponding portion of the packaging substrate panel.

According to some implementations, the present disclosure relates to a molding system that includes a molding chamber having a floor and a ceiling, and configured to receive a panel having an upper side and a lower side, where the lower side of the panel includes a plurality of pockets. The molding system further includes a delivery system configured to introduce molding compound to the molding chamber to allow formation of an overmold on the upper side of the panel. The molding system further includes a plurality of support features configured to fit at least partially into and provide support for the corresponding pockets during the formation of the overmold.

In some embodiments, the plurality of support features can be part of a support plate capable of being placed on and removed from the floor of the molding chamber. In some embodiments, the plurality of support features can be integral part of the floor of the molding chamber.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows a packaged radio-frequency (RF) device having a cavity.

FIGS. 2A and 2B show side sectional and underside views of a packaged RF device having a packaging substrate with an upper side and a lower side.

FIG. 3 shows that in some embodiments, units that will become packaged RF devices can be fabricated partially or fully while attached together in a panel.

FIG. 4 shows that in some embodiments, the RF device of FIG. 1 can include a wire-shielded package.

FIG. 5 shows that in some embodiments, the RF device of FIG. 1 can include a shielded package having a non-wire component that provides electrical connection between an upper conductive layer and a ground plane.

FIG. 6 shows that in some embodiments, the RF device of FIG. 1 can include a shielded package having a conformal conductive layer that is electrically connected to a ground plane.

FIGS. 7A-7C show an example of a mechanical problem that can arise during processing of the upper side of a substrate panel.

FIG. 8 shows a photograph of a side sectional view of a partially completed panel that has been deformed during a molding process.

FIG. 9 shows a photograph of a side sectional view of a partially completed panel that has not be deformed during a molding process.

FIG. 10 shows a perspective view of a support block that can provide underside support for a packaging substrate so as to allow the packaging substrate to maintain mechanical integrity similar to the example of FIG. 9.

FIG. 11 depicts an underside support that can be provided for pockets by the support block of FIG. 10.

FIG. 12 shows an example of a pocket support configuration where pedestals can be provided on a floor of a molding apparatus.

FIG. 13 shows an example of a pocket support configuration where pedestals can be provided on a support plate.

FIGS. 14A-14D show more detailed examples of how a panel having underside pockets can be processed with the example support plate of FIG. 13.

FIG. 15 shows that each pedestal of a support plate can be dimensioned relative to the dimensions of a underside pocket of a panel.

FIG. 16 shows an example where pedestals of a support plate can have a height that is less than a depth of underside pockets of a panel.

FIG. 17 shows an example where pedestals of a support plate can have a height that is greater than a depth of underside pockets of a panel.

FIG. 18 shows that in some embodiments, a support plate can be configured to include more than one pedestal for each pocket.

FIG. 19 shows that in some embodiments, pedestals of a support plate can be dimensioned to account for presence of features such as contact features formed on the underside of a panel.

FIG. 20 shows that in some embodiments, an upper surface of each pedestal of a support plate can be configured to provide improved engagement with the regions with and without contact features on the underside of a panel.

FIG. 21 shows an underside view of the example panel of FIG. 20.

### DETAILED DESCRIPTION OF SOME EMBODIMENTS

The headings provided herein, if any, are for convenience only and do not necessarily affect the scope or meaning of the claimed invention.

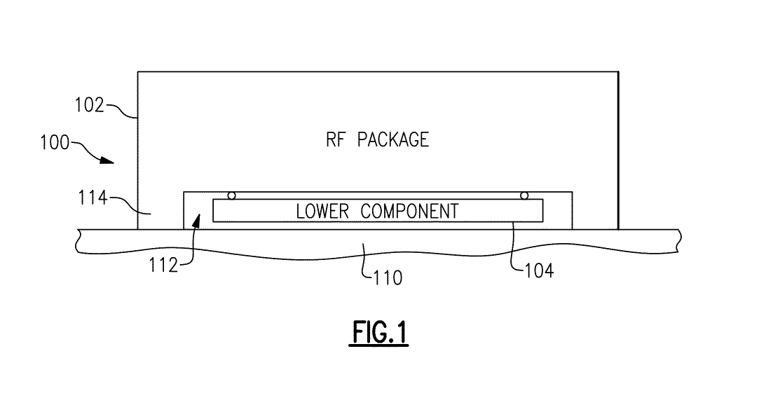

FIG. 1 shows a packaged radio-frequency (RF) device 100 having a cavity 112 (also referred to herein as a pocket). A component 104 is shown to be mounted within such a cavity. The packaged RF device 100 can be a dual-sided package having a shielded package 102 which includes one or more upper components, and one or more lower components such as the example component 104. For the purpose of description, a lower side of the shielded package 102 can include the side that is to be mounted onto a circuit board 110 such as a phone board. Although not shown in FIG. 1, it will be understood that the shielded package 102 can include a packaging substrate that allows mounting of the foregoing upper component(s) on its upper side (when oriented as shown in FIG. 1) and lower component(s) on its lower side (e.g., within the cavity 112). Accordingly, the dual-side property can include such upper component(s) mounted over the substrate and lower component(s) mounted under the substrate.

Additional examples concerning such a dual-sided packaged module can be found in U.S. Application No. ______ entitled DEVICES AND METHODS RELATED TO DUAL-SIDED RADIO-FREQUENCY PACKAGE HAVING SUBSTRATE CAVITY (Attorney Docket No. 75900-50174US), the disclosure of which is hereby expressly incorporated by reference herein in its entirety.

For the purpose of description, it will be understood that a lower component can include any device that can be mounted on the substrate and/or the circuit board. Such a device can be, for example, an active radio-frequency (RF) device or a passive device that facilitates processing of RF signals. By way of non-limiting examples, such a device can include a die such as a semiconductor die, an integrated passive device (IPD), a surface-mount technology (SMT) device, and the like. In some embodiments, the lower component as described herein can be electrically coupled to the one or more upper component through, for example, the substrate.

As further shown in FIG. 1, the cavity 112 under the shielded package 102 can be defined by a recess on the underside of the shielded package 102. Such a recess can be defined by one or more structures configured to allow mounting of the shielded package 102 on the circuit board 110. In the example shown in FIG. 1, the cavity 112 is depicted as being formed generally in the middle portion of the shielded package 102, such that four walls 114 surround the lateral sides of the cavity 112 and allow mounting of the shielded package 102. In some embodiments, the one or more structures such as the four walls 114 can be integral part of the shielded package 102 (e.g., cavity can be formed on the underside of a substrate), be added on to the shielded package 102, or any combination thereof. The one or more structures such as the four walls 114 can be configured so that when mounted to the circuit board 110, there is sufficient vertical space between the upper surface of the circuit board 110 and the inner surface of the cavity for the lower component 104. Examples related to fabrication of dual-sided packages having such a configuration are described herein in greater detail.

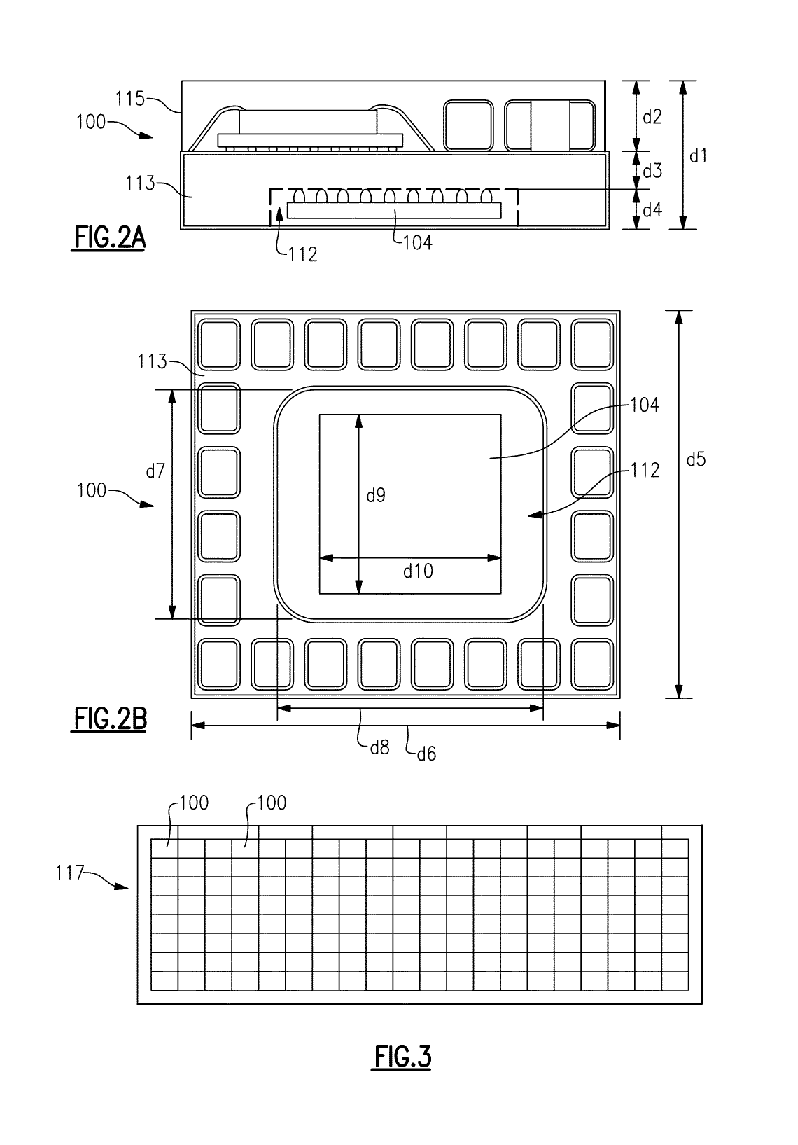

FIGS. 2A and 2B show side sectional and underside views of a packaged RF device 100 having a packaging substrate 113 with an upper side and a lower side. Mounted on the upper side of the packaging substrate 113 are example components such as wirebond die, surface-mount technology (SMT) device, etc. Such upper-side components are shown to be encapsulated by an overmold 115. The underside of the packaging substrate 113 is shown to define a cavity 112, with an example component 104 mounted to the packaging substrate 113 and substantially within the cavity 112.

As one can see in the example of FIGS. 2A and 2B, the volume of the cavity 112 can occupy a significant portion of the packaging substrate 113 to allow the component 104 to have appropriately significant dimensions. For examples, dimensions d1-d10 as shown in FIGS. 2A and 2B can be as follows in the context of an example 5 mm×5 mm package RF module: D1=0.800 mm, d2=0.33 mm, d3=0.25 mm, d4=0.22 mm, d5=5.00 mm, d6=5.00 mm, d7=3.55 mm, d8=3.55 mm, d9=2.76 mm, d10=2.15 mm.

Based on the foregoing example, one can see that the lateral area of the cavity 112 constitutes a significant portion of the lateral area of the packaging substrate 113. One can also see that while the packaging substrate has a full thickness (e.g., d3+d4=0.47 mm) at areas surrounding the cavity 112, its thickness (d3) within the cavity 112 is significantly less (e.g., d3=0.25 mm). As described herein, such lateral dimensions and/or height of the cavity 112 can result in deformation of the thinned portion (dimension d3) of the packaging substrate during one or more processing steps associated with manufacturing of packaged RF devices such as the example of FIGS. 1 and 2.

FIG. 3 shows that in some embodiments, units that will become packaged RF devices 100 such as the examples of FIGS. 1 and 2 can be fabricated partially or fully while attached together in a panel 117. In situations where each of such units includes the cavity 112 of FIGS. 2A and 2B, the foregoing deformation problem associated with the cavity 112 can affect some or all of units of the panel 117.

Described herein are devices and methods for reducing or eliminating such deformation problems during manufacturing of packaged RF devices such as modules. While various examples are described in the context of RF devices, it will be understood that one or more features of the present disclosure can also be implemented in other packaging applications.

FIGS. 4-6 show non-limiting examples of the packaged RF module of FIG. 1. The examples of FIGS. 4-6 are dual-sided packages having underside pockets. Such dual-sided packages are described herein as including respective shielded packages. However, it will be understood that one or more features of the present disclosure can also be utilized for manufacturing of dual-sided packages without shielding functionality. Further, it will be understood that one or more features of the present disclosure can also be utilized for manufacturing of single-sided packages having pockets.

FIG. 4 shows that in some embodiments, the shielded package 102 of FIG. 1 can be a wire-shielded package 200. The wire-shielded package 200 is shown to include a packaging substrate 202 (e.g., a laminate substrate) and a plurality of components mounted thereon. For example, a first component 124 is depicted as being mounted on the upper surface of the packaging substrate 202, and electrical connections between the component 124 and the packaging substrate 202 can be facilitated by, for example, wirebonds 128. In another example, a second component 126 is shown to be mounted on the upper surface of the packaging substrate 202 in a die-attach configuration. Electrical connections between the component 126 and the packaging substrate 202 can be facilitated by, for example, die-attach features.

In the example of FIG. 4, a plurality of shielding wires 130 (e.g. shielding wirebonds) are shown to be provided over the packaging substrate 202. Such shielding wires 130 can be electrically connected to a ground plane (not shown) within the packaging substrate 202. The shielding wires 130 as well as the mounted components 124, 126 are shown to be encapsulated by an overmold 132. The upper surface of the overmold 132 can be configured to expose the upper portions of the shielding wires 130, and an upper conductive layer 134 can be formed thereon. Accordingly, a combination of the upper conductive layer 134, the shielding wires 130, and the ground plane can define a shielded volume or region. Such a configuration can be implemented to provide shielding functionality between regions within and outside of the shielded package 200, and/or between regions that are both within the shielded package 200. Additional details concerning such shielding can be found in, for example, U.S. Pat. No. 8,373,264 entitled SEMICONDUCTOR PACKAGE WITH INTEGRATED INTERFERENCE SHIELDING AND METHOD OF MANUFACTURE THEREOF which is expressly incorporated by reference in its entirely.

In the example of FIG. 4, the underside of the packaging substrate 202 is shown to include an underside pocket 204, and a lower component 104 is shown to be mounted therein to thereby form a dual-sided package 100. The portion of the packaging substrate 202 surrounding the pocket 204 is shown to be configured to allow mounting of the dual-sided package 100. For example, the dual-sided package 100 is shown to be mounted on a circuit board 110 such as a phone board with contact pads 206.

FIG. 5 shows that in some embodiments, the shielded package 102 of FIG. 1 can be a shielded package 210 having a non-wire component 150 that provides electrical connection between an upper conductive layer 154 and a ground plane (not shown) within a packaging substrate 212 (e.g., a laminate substrate). In addition to the component 150, the packaging substrate 212 is shown to have a plurality of components mounted thereon. For example, a first component 144 is depicted as being mounted on the upper surface of the packaging substrate 212, and electrical connections between the component 144 and the packaging substrate 212 can be facilitated by, for example, wirebonds 148. In another example, a second component 146 is shown to be mounted on the upper surface of the packaging substrate 212 in a die-attach configuration. Electrical connections between the component 146 and the packaging substrate 212 can be facilitated by, for example, die-attach features.

In the example of FIG. 5, the component 150 is shown to provide an electrical connection between the upper conductive layer 154 and the ground plane (not shown) within the packaging substrate 212. The component 150 as well as the mounted components 144, 146 are shown to be encapsulated by an overmold 152. The upper surface of the overmold 152 can be configured to expose the upper portion of the component 150, and the upper conductive layer 154 can cover such an exposed portion as well as the remaining upper surface of the overmold 152. Accordingly, a combination of the upper conductive layer 154, the component 150, and the ground plane can define a shielded volume or region. Such a configuration can be implemented to provide shielding functionality between regions within and outside of the shielded package 210, and/or between regions that are both within the shielded package 210. Additional details concerning such shielding can be found in, for example, U.S. Publication No. 2014/0307394, entitled APPARATUS AND METHODS RELATED TO CONFORMAL COATING IMPLEMENTED WITH SURFACE MOUNT DEVICES, which is expressly incorporated by reference in its entirely.

In the example of FIG. 5, the underside of the packaging substrate 212 is shown to include an underside pocket 214, and a lower component 104 is shown to be mounted therein to thereby form a dual-sided package 100. The portion of the packaging substrate 212 surrounding the pocket 214 is shown to be configured to allow mounting of the dual-sided package 100. For example, the dual-sided package 100 is shown to be mounted on a circuit board 110 such as a phone board with contact pads 216.

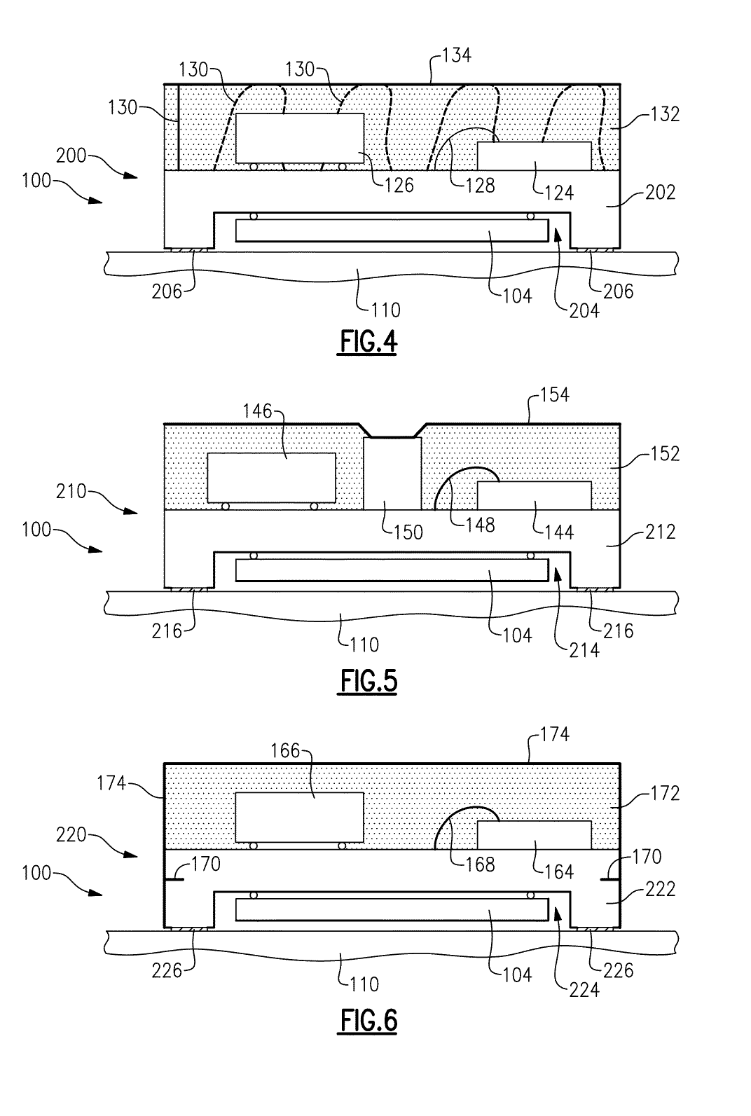

FIG. 6 shows that in some embodiments, the shielded package 102 of FIG. 1 can be a shielded package 220 having a conformal conductive layer 174 that is electrically connected to a ground plane (not shown) within a packaging substrate 222 (e.g., a laminate substrate or a ceramic substrate). The shielded package 220 is shown to include a plurality of components mounted on the packaging substrate 222. For example, a first component 164 is depicted as being mounted on the upper surface of the packaging substrate 222, and electrical connections between the component 164 and the packaging substrate 222 can be facilitated by, for example, wirebonds 168. In another example, a second component 166 is shown to be mounted on the upper surface of the packaging substrate 222 in a die-attach configuration. Electrical connections between the component 166 and the packaging substrate 222 can be facilitated by, for example, die-attach features.

In the example of FIG. 6, the mounted components 164, 166 are shown to be encapsulated by an overmold 172. The conformal conductive layer 174 is shown to generally cover the upper surface of the overmold 172, as well as side walls (e.g., all four side walls) defined by the sides of the overmold 172 and the packaging substrate 222. The packaging substrate 222 is shown to include conductive features 170 having portions exposed on the sides of the packaging substrate, and also electrically connected to the ground plane (not shown), to thereby provide electrical connections between the conformal conductive layer 174 and the ground plane. Accordingly, a combination of the conformal conductive layer 174 and the ground plane can define a shielded volume or region. Such a configuration can be implemented to provide shielding functionality on one or more sides of the shielded package 220.

In the example of FIG. 6, the underside of the packaging substrate 222 is shown to include an underside pocket 224, and a lower component 104 is shown to be mounted therein to thereby form a dual-sided package 100. The portion of the packaging substrate 222 surrounding the pocket 224 is shown to be configured to allow mounting of the dual-sided package 100. For example, the dual-sided package 100 is shown to be mounted on a circuit board 110 such as a phone board with contact pads 226.

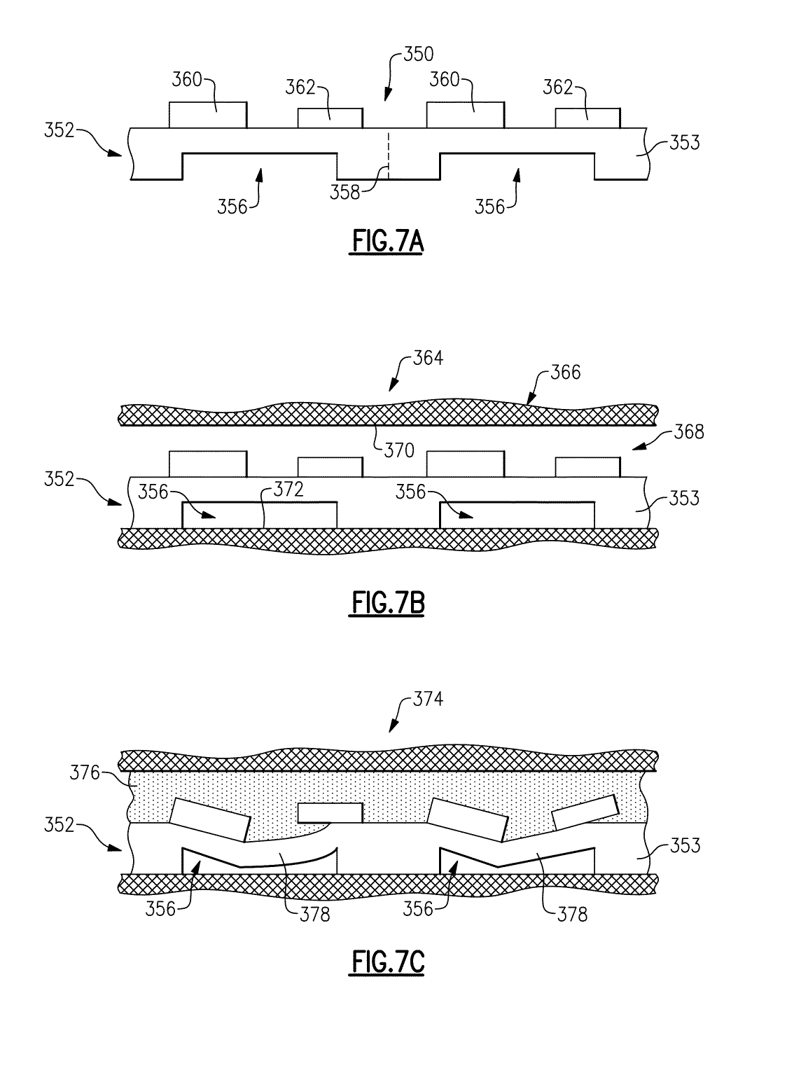

As described herein, some of the pocket-based dual-sided packages (e.g., FIGS. 4 and 5) can undergo most or all of fabrication steps while in a panel format. FIGS. 7A-7C show an example of a mechanical problem that can arise during processing of the upper side of a substrate panel.

FIG. 7A shows a fabrication state 350 where a partially completed panel 352 includes a substrate panel 353 and components 360, 362 mounted on each region that will become an individual unit. Each region is defined by borders 358, and also includes a pocket 356 that has been pre-formed on the underside of the substrate panel 353.

FIG. 7B shows a fabrication state 364 where the partially completed panel 352 of FIG. 7A is placed in a molding apparatus 366 to form an overmold layer over the substrate panel 353. Such a molding apparatus is shown to include a volume 368 defined by a ceiling 370 and a floor 372. The ceiling 370 is shown to be positioned to provide a desired vertical clearance over the components to thereby allow the overmold to substantially encapsulate the components. In embodiments having shielding wirebonds, such a vertical height of the ceiling can be based on the height of the shielding wirebonds.

The floor 372 is shown to be substantially flat to support the substrate panel 353. Because of such flatness, the thinned portions of the substrate panel 353 above the pockets 356 are unsupported from below.

FIG. 7C shows a fabrication state 374 where molding compound 376 has been introduced into the volume between the substrate panel 353 and the ceiling 370 (see FIG. 7B). In many of such molding processes, the molding compound is introduced with pressure, and accordingly, the molding compound itself exerts pressure on the substrate panel 353. Because the thinned portions (378) of the substrate panel 353 above the pockets 356 are weaker than the portions between the pockets, the pressure of the molding compound can deform the thinned portions, thereby making the overmolded panel un-usable.

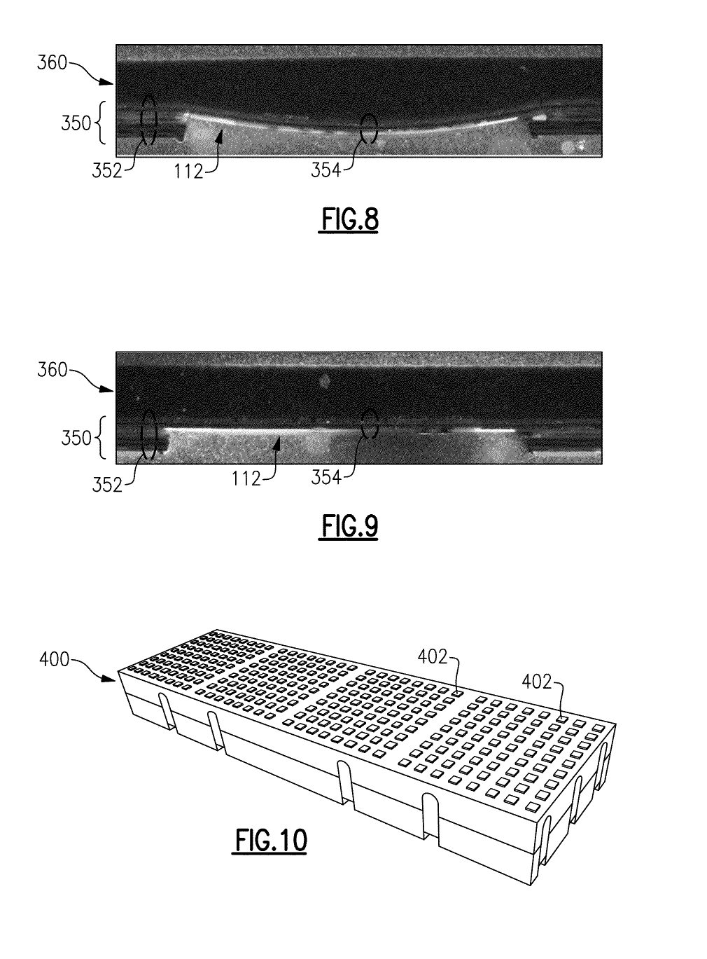

FIG. 8 shows an example of the foregoing deformation resulting from the pressure of the molding compound. More particularly, FIG. 8 shows a photograph of a side sectional view of a partially completed panel that includes a substrate 350 and an overmold 360 formed on the substrate 350. The example substrate 350 is a laminate substrate with an underside pocket 112 as described herein. The region outside of the pocket 112 is shown to have a full set of layers, indicated as 352. The region inside of the pocket 112 is shown to have a reduced number of layers, indicated as 354.

When such a panel is positioned on a flat surface, the underside of the region 352 engages the flat surface, and the underside of the region 354 (inside the pocket 112) remains generally unsupported from the bottom. Accordingly, due to such lack of underside support for the region 354, application of pressure on the upper side of the substrate 350 can result in deformation of the region 354.

Formation of an overmold (such as the overmold 360 of FIG. 8) can provide such a pressure on the upper side of the substrate 350. Thus, in the example of FIG. 8, the region 354 is shown to be bowed downward due to the pressure of the overmold 360 and the lack of support underneath. The region 354 having a reduced thickness (e.g., due to the reduced number of layers) can also make such deformation more pronounced.

As described herein, such a deformation of the pocket 112 is problematic for a number of reasons. For example, one or more components mounted above the substrate 350 can be impacted due to the concave deformation (when viewed from the upper side of the substrate 350). In another example, the convex deformation of the ceiling of the pocket 112 (when viewed from the lower side of the substrate 350) can result in much of the space (of the pocket 112) being made un-usable for mounting of a component therein.

FIG. 9 is a photograph of a side sectional view of a partially completed panel that includes a substrate 350 similar to the example of FIG. 8. In FIG. 9, however, an overmold 360 formed on the substrate 350 does not deform the region 354, such that the integrity of the pocket 112 is preserved during the molding process. Such a desirable feature can be provided by implementing an underside support for the region 354 utilizing, for example, a support block having a pedestal that fits into the pocket 112.

FIG. 10 shows a perspective view of a support block 400 that can provide underside support for regions of a packaging substrate associated with pockets. In the example of FIG. 10, an array of pedestal features 402 are arranged and dimensioned so as to allow a packaging substrate panel with a corresponding array of underside pockets to be positioned thereon. As described herein, each pedestal feature 402 can fit into the corresponding pocket, and the upper surface of the pedestal feature 402 can provide support for the thinned region of the packaging substrate.

The support block 400 is an example of how undersides of an array of pockets can be supported during, for example, a compression molding process. A more general example of such underside support is depicted in FIG. 11. More particularly, FIG. 11 shows that in some embodiments, support (depicted as arrows 382) can be provided on the underside of pockets 356 for processing of partially completed panel 352 such as in a processing state 380. Although such support of the pockets is described in the context of overmold formation, it will be understood that the support can also be provided in other stages. It will also be understood that although the technique of providing support for the pockets is described in the context of fabrication of dual-sided packages, such a technique can also be utilized during fabrication of other types of packages, including one-sided packages.

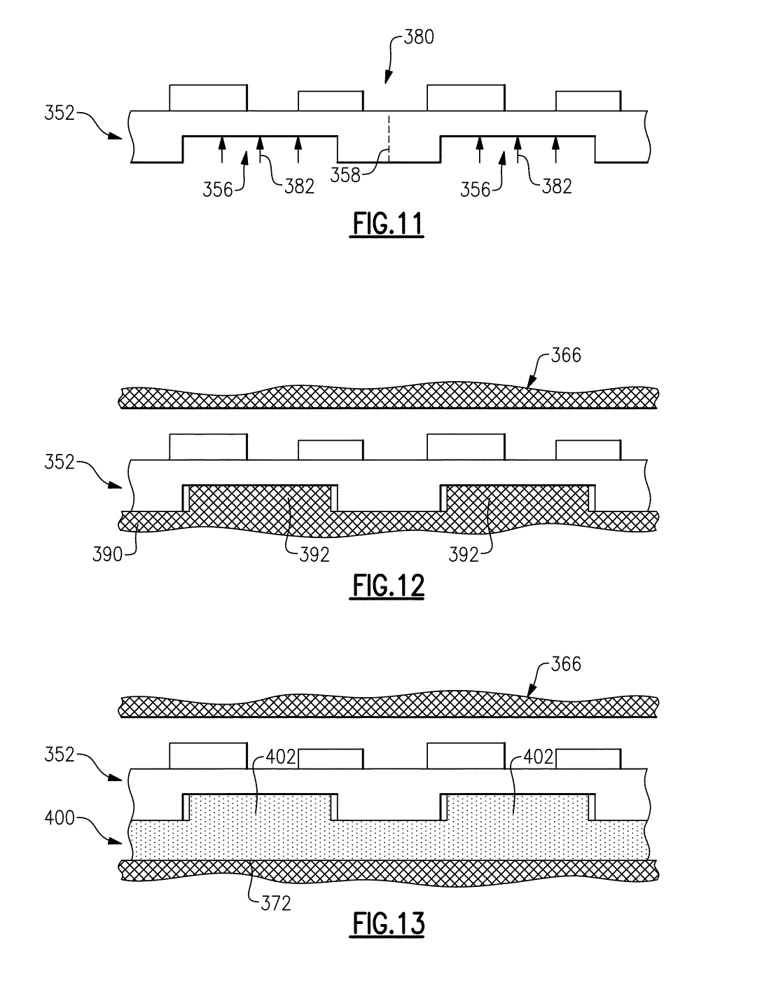

FIG. 12 shows an example of pocket support where pedestals 392 are provided on the floor of a molding apparatus 366. In some embodiments, such a floor and the pedestals 392 can be integral parts of a lower assembly of the overmold apparatus 366. With such a support system, a partially completed panel 352 placed in the molding apparatus 366 is shown to have the thinned portions of the substrate panel above the pockets supported by the pedestals 392. Accordingly, the thinned portions above the pockets will not deform as in the example of FIGS. 7C and 8 when under pressure from the molding compound.

In some applications, it may be desirable to be able to use an existing molding apparatus, instead of having its floor be configured with pedestals. In such applications, a support plate having pedestals can be implemented. FIG. 13 shows an example of a support plate 400 having a plurality of pedestals 402 dimensioned to provide support for the thinned portions of a partially completed panel 352. The underside of the support plate 400 can be flat so as to provide a flat-on-flat engagement with a flat floor 372 of a molding apparatus 366. Accordingly, an existing molding apparatus (having a flat floor) can be adjusted to accommodate the extra thickness due to the support plate 400, and be utilized to form an overmold with the thinned portions supported appropriately.

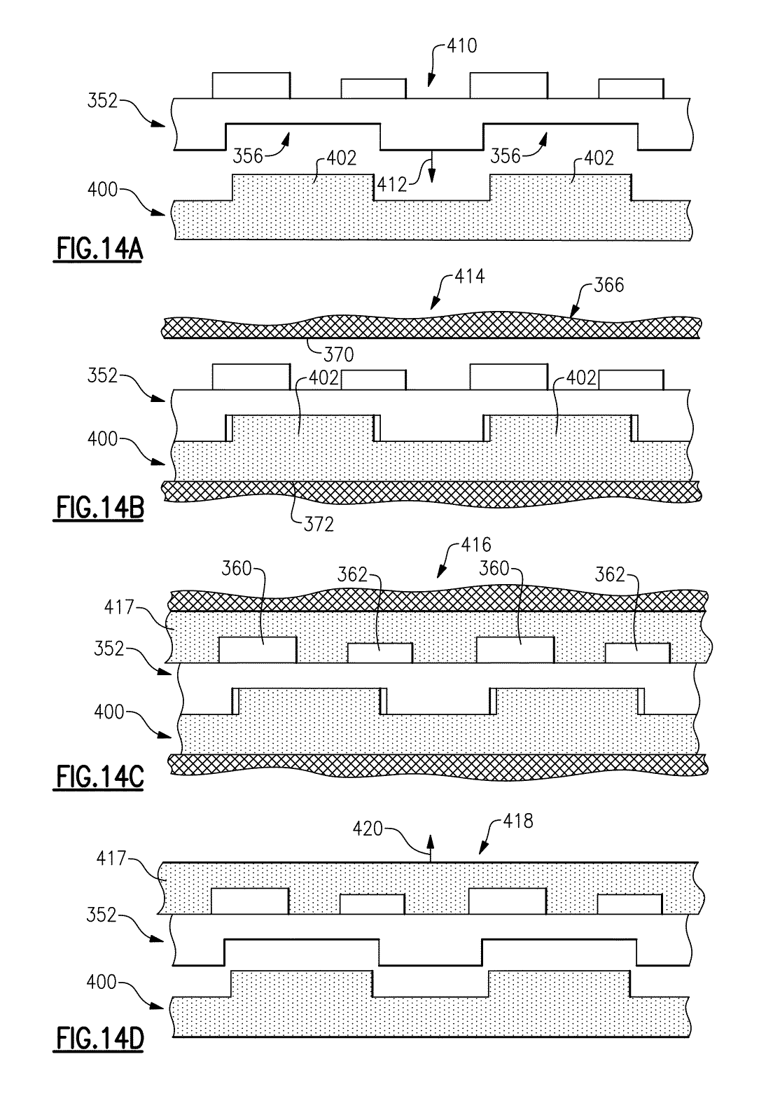

FIGS. 14A-14D show more detailed examples of how a panel having underside pockets can be processed with a support plate described above in reference to FIG. 13. In FIG. 14A, a fabrication state 410 can include a partially completed panel 352 having a plurality of underside pockets 356, and components already mounted on the upper side of a packaging substrate. Such a partially completed panel is shown to be positioned (arrow 412) on a support plate 400 having a plurality of pedestals dimensioned to fit into the underside pockets 356 and provide support for the corresponding thinned portions of the packaging substrate.

In FIG. 14B, a fabrication state 414 can include an assembly of the partially completed panel 352 and the support plate 400, resulting from FIG. 14A, being placed in a molding apparatus 366. With a ceiling 370 and a floor 372 adjusted approriately, a desired space for molding can be provided above the packaging substrate.

In FIG. 14C, a fabrication state 416 can include molding compound 417 being introduced into the space between the packaging substrate and the ceiling of the molding apparatus. Such molding compound is shown to encapsulate the components 360, 362. The thinned portions of the packaging substrate are inhibited from deforming under the pressure of the molding compound 417 due to the support provided by the pedestals of the support plate 400.

In FIG. 14D, a fabrication state 418 can include an assembly of the panel 352 and the overmold layer 417 being separated (arrow 420) from the support plate 400. Such a separation can occur after the overmold layer 417 is set, and the assembly of the overmold layer, the panel 352, and the support plate 400 can be removed from the molding apparatus.

FIG. 15 shows that each pedestal of a support plate 400 can be dimensioned relative to the dimensions of a underside pocket of a panel 352 it is intended to support. For example, the pedestal can have a lateral dimension of d3 to be able to fit into a corresponding lateral dimension d1 of the pocket. A height d4 of the pedestal can be selected such that the upper surface of the pedestal provides support for the thinned portion at the depth d2 of the pocket as described herein.

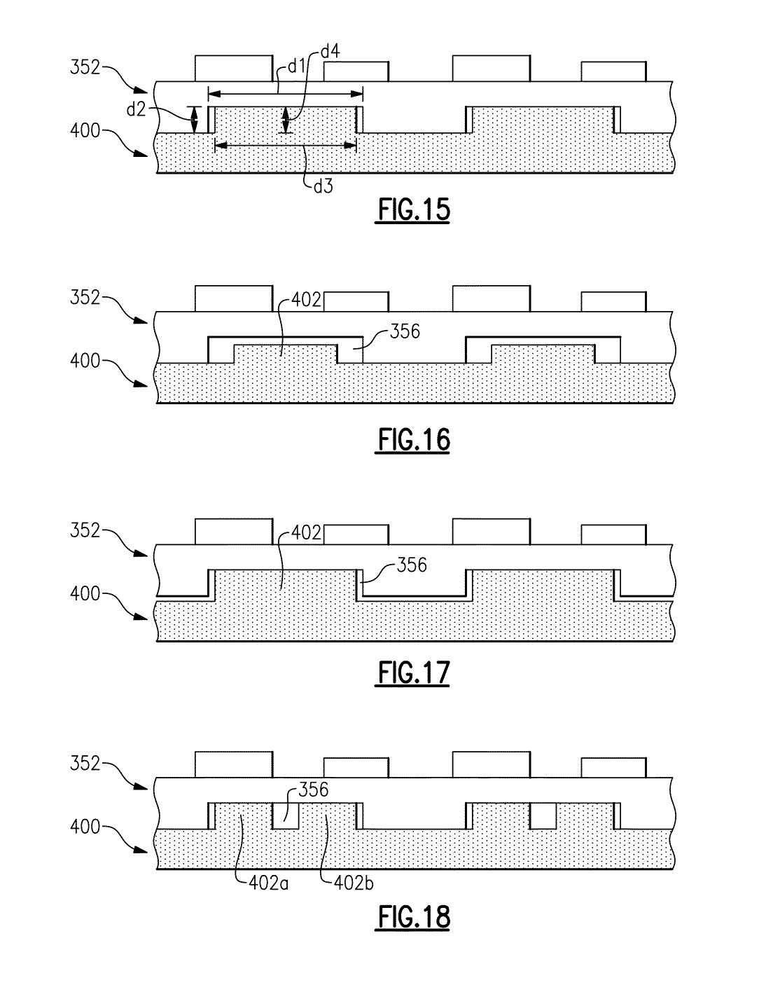

In the examples described in reference to FIGS. 14A-14D, the pedestals are depicted as having a height (d4 in FIG. 15) that is substantially the same as the depth (d2) of the pockets, such that the upper surface of each pedestal engages the thinned portion above the corresponding pocket. At the same time, the lower surface of the un-thinned portions are shown to engage the surfaces between the pedestals. In some embodiments, the pedestals and the pockets do not necessarily need to fit in such flush manner. FIGS. 16 and 17 show examples of non-flush fits that can still provide support functionality during a molding process.

In an example of FIG. 16, pedestals 402 of a support plate 400 are shown to have a height that is less than a depth of underside pockets 356 of a panel 352. Accordingly, a gap exists between the upper surface of the pedestal 402 and the underside of the thinned portion. If such a gap is sufficiently small, whatever deformation that results during the molding process may not be significant enough to be detrimental.

In an example of FIG. 17, pedestals 402 of a support plate 400 are shown to have a height that is greater than a depth of underside pockets 356 of a panel 352. Accordingly, the upper surface of the pedestal 402 engages the underside of the thinned portion, and a gap exists between the surface of the support plate 400 between the pedestals 402 and the underside of the thick portions of the panel 352. Because the thick portions are less likely to deform under pressure, such a configuration can be utilized without detrimental effect.

In the examples described in reference to FIGS. 12-17, there is one pedestal for each pocket. FIG. 18 shows that there can be more than one pedestal for each pocket. For example, a support plate 400 is shown to include a plurality of pedestals 402a, 402b dimensioned and arranged so as to provide support for a thinned portion associated with a corresponding pocket 356 of a panel 352.

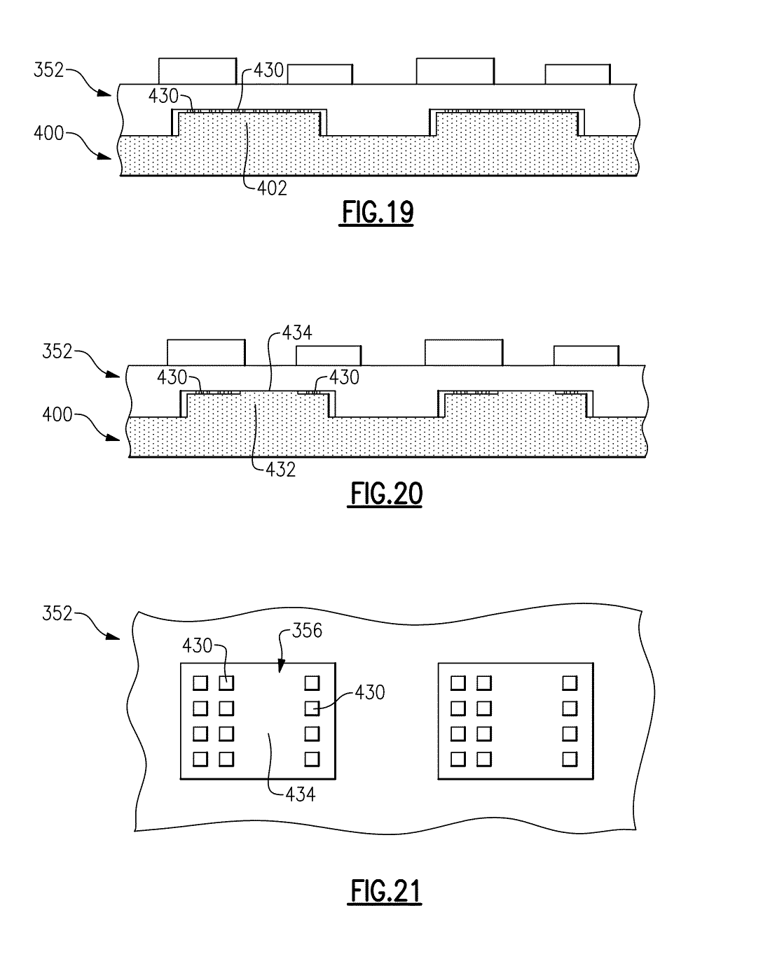

In some of the examples described herein, engagement surfaces between a given pedestal and the ceiling portion of a corresponding pocket are depicted as being flat. In some embodiments, there may be features (e.g., contact features) on the ceiling portion to facilitate mounting of a component within the pocket. Accordingly, FIG. 19 shows that in some embodiments, pedestals 402 of a support plate 400 can be dimensioned to account for the presence of features 430 such as the contact features formed on the underside of a panel 352.

When such features (430) (e.g., contact features) on the underside of a panel are sufficiently thick, and/or if such features are distributed in some manner (e.g., grouped so as to leave a significant region without features), there may be local area(s) on the underside of a panel (352) with less support if an upper surface of each pedestal of a support plate (400) is flat.

FIGS. 20 and 21 show that in some embodiments, an upper surface of each pedestal 432 of a support plate 400 can be configured to provide improved engagement with the regions with and without the contact features. For example, FIG. 21 shows an arrangement of contact features 430 within each pocket 356, such that a region 434 of the ceiling of the pocket 356 does not have any contact feature. To provide support for such a region as well as the regions with the contact features 430, the example pedestal 432 in FIG. 20 is shown to include an additional support feature (e.g., another pedestal) implemented on the upper surface of the pedestal 432. Such an additional support feature can be dimensioned so as to allow its upper surface to engage the region 434 without the contact features. The remaining portion of the upper surface of the main pedestal (402) can engage the contact features.

General Comments

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A device for fabricating radio-frequency (RF) modules, the device comprising a support plate having a receiving side configured to receive a packaging substrate panel having a plurality of pockets, the receiving side including a plurality of support features, each support feature dimensioned to fit at least partially into the corresponding pocket and provide support for a portion of the packaging substrate panel associated with the pocket.

2. The device of claim 1 wherein the support feature includes a pedestal implemented on the receiving side.

3. The device of claim 2 wherein the packaging substrate includes an upper side and a lower side when positioned on the receiving side of the support plate, such that the pockets are on the lower side of the packaging substrate and the portion of the packaging substrate panel forms a ceiling for the corresponding pocket.

4. The device of claim 3 wherein the support plate is configured to provide underside support for the ceilings of the pockets during a processing operation in which pressure is applied on the upper side of the packaging substrate panel.

5. The device of claim 4 wherein the processing operation includes a compression molding process implemented to form an overmold layer over the packaging substrate panel.

6. The device of claim 5 wherein the support plate is an integral part of a platform for holding the packaging substrate panel during the compression molding process.

7. The device of claim 5 wherein the support plate is configured to fit into a molding cavity of a compression molding apparatus that is configured to receive a substantially flat packaging substrate panel.

8. The device of claim 4 wherein the underside support is provided at least in part by the pedestals to inhibit or reduce deformation of the ceilings of the pockets.

9. The device of claim 8 wherein the deformation includes each ceiling bowing into the corresponding pocket.

10. The device of claim 3 wherein the pedestal includes a substantially flat surface for supporting the corresponding ceiling of the pocket.

11. The device of claim 3 wherein the pedestal includes one or more support features dimensioned to accommodate features on the corresponding ceiling of the pocket.

12. The device of claim 3 wherein the pedestal has a rectangular shape with a height dimensioned to provide support for at least a selected area of the ceiling of the pocket.

13. The device of claim 12 wherein the height is selected such that an upper surface of the pedestal is in contact with the ceiling of the pocket when providing the support for the selected area.

14. A method for fabricating radio-frequency (RF) modules, the method comprising:
positioning a packaging substrate panel for a processing operation in which pressure is applied on a first side of the packaging substrate panel, the packaging substrate panel including a plurality of pockets on a second side opposite from the first side; and
supporting, on the second side, a portion of the packaging substrate panel associated with each pocket to reduce deformation of the pocket resulting from the pressure applied on the first side.

15. The method of claim 14 further comprising performing the processing operation in which the pressure is applied on the first side of the packaging substrate panel.

16. The method of claim 15 wherein the processing operation includes a compression molding operation to form an overmold layer on the first side of the packaging substrate panel.

17. The method of claim 14 wherein the supporting of the portion of the packaging substrate panel includes positioning the packaging substrate panel on a support plate having a plurality of support features, each support feature dimensioned to fit at least partially into the corresponding pocket and provide support for the corresponding portion of the packaging substrate panel.

18. A molding system comprising:
a molding chamber having a floor and a ceiling, and configured to receive a panel having an upper side and a lower side, the lower side of the panel including a plurality of pockets;
a delivery system configured to introduce molding compound to the molding chamber to allow formation of an overmold on the upper side of the panel; and
a plurality of support features configured to fit at least partially into and provide support for the corresponding pockets during the formation of the overmold.

19. The molding system of claim 18 wherein the plurality of support features are part of a support plate capable of being placed on and removed from the floor of the molding chamber.

20. The molding system of claim 18 wherein the plurality of support features are integral part of the floor of the molding chamber.
